(19) United States
(12) Patent Application Publication
(10) Pub. No.: US 2018/0233335 A1
(43) Pub. Date: Aug. 16, 2018

(54) PROCESSING DEVICE AND COLLIMATOR

(71) Applicant: Kabushiki Kaisha Toshiba, Minato-ku (JP)

(72) Inventors: Shiguma KATO, Yokohama (JP); Takahiro TERADA, Yokohama (JP); Yoshinori TOKUDA, Yokohama (JP); Masakatsu TAKEUCHI, Obu (JP); Yasuhiro AOYAMA, Yokkaichi (JP)

(73) Assignee: Kabushiki Kaisha Toshiba, Minato-ku (JP)

(21) Appl. No.: 15/750,872

(22) PCT Filed: Dec. 19, 2016
(86) PCT No.: PCT/JP2016/087819

§ 371 Date: Feb. 7, 2018

(30) Foreign Application Priority Data
Mar. 14, 2016 (JP) 2016-050217

(51) Int. Cl. H01J 37/34; C23C 14/34; H01J 37/32; H01L 21/285

(52) U.S. Cl. CPC H01J 37/3447; C23C 14/34; H01L 21/2855; H01J 37/32422; H01J 37/3405

(57) ABSTRACT

A processing device according to one embodiment includes an object placement unit, a source placement unit, and a collimator. An object is placed on the object placement unit. The source placement unit is arranged apart from the object placement unit, and has a particle source placed thereon, the particle source being capable of ejecting particle toward the object. The collimator is arranged between the object placement unit and the source placement unit, includes walls, and is provided with through holes formed by the walls. The walls include a first inner surface facing the through hole. The first inner surface includes a first portion made of a first material capable of ejecting the particle, and a second portion made of a second material, and arranged with the first portion in the first direction and closer to the object placement unit than the first portion.

### FIELD

Embodiments of the present invention relate to a processing device and a collimator.

### BACKGROUND

For example, a sputtering device for forming a metal film on a semi conductor wafer includes a collimator for adjusting the directions of metal particles to be formed into a film. The collimator includes walls that form a number of through holes, and allows particles flying in a direction substantially perpendicular to an object to be processed such as a semiconductor wafer to pass therethrough and blocks obliquely flying particles.

### CITATION LIST

### Patent Literature

Patent Literature 1: JP 7-316806 A

### SUMMARY OF THE INVENTION

### Problem to be Solved by the Invention

Generation of the obliquely flying particles may decrease the utilization efficiency of particles.

### Means for Solving Problem

A processing device according to one embodiment includes an object placement unit, a source placement unit, and a collimator. The object placement unit is configured to have an object placed thereon. The source placement unit is arranged apart from the object placement unit and configured to have a particle source placed thereon, the particle source being capable of ejecting a particle toward the object. The collimator is configured to foe arranged between the object placement unit and the source placement unit, includes a plurality of walls, and is provided with a plurality of through holes formed by the plurality of walls and extending in a first direction from the source placement unit to the object placement unit. The plurality of walls include a first inner surface facing the through hole. The first inner surface includes a first portion made of a first material capable of ejecting the particle, and a second portion made of a second material different from the first material, and arranged with the first portion in the first direction and closer to the object placement unit than the first portion.

### BRIEF DESCRIPTION OF DRAWINGS

FIG. 1 is a cross-sectional view schematically illustrating a sputtering device according to a first embodiment.

FIG. 2 is a plan view illustrating a collimator of the first embodiment.

FIG. 3 is a cross-sectional view illustrating a part of the sputtering device of the first embodiment.

FIG. 4 is a cross-sectional view schematically illustrating a part of the collimator of the first embodiment.

FIG. 5 is a cross-sectional view illustrating a part of a collimator according to a second embodiment.

FIG. 6 is a cross-sectional view schematically illustrating a part of a collimator according to a third embodiment.

### DETAILED DESCRIPTION

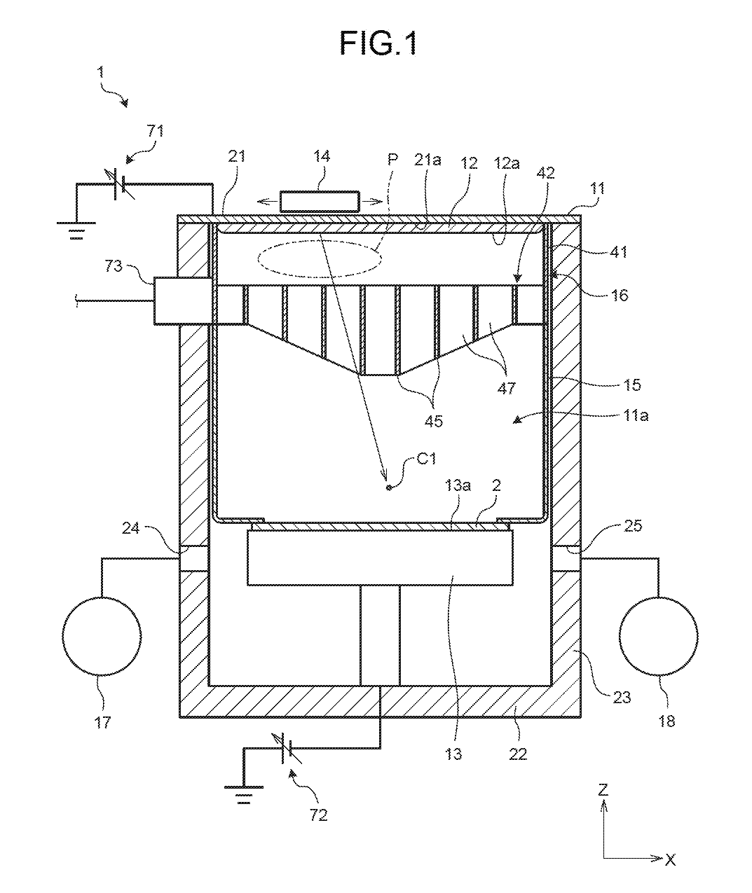

Hereinafter, a first embodiment will be described with reference to FIGS. 1 to 4. In this specification, basically, the vertical upward direction is defined as an upward direction, and the vertical downward direction is defined as a downward direction. Further, in this specification, a plurality of expressions is sometimes written about configuration elements of the embodiments and the description of the elements. Other expressions that are not written may foe made for the configuration elements and the description for which the plurality of expressions has been made. Further, other expressions that are not written may be made for configuration elements and description for which a plurality of expressions has not been made.

FIG. 1 is a cross-sectional view schematically illustrating a sputtering device 1 according to the first embodiment. The sputtering device 1 is an example of a processing device, and may be referred to as a semiconductor manufacturing device, a manufacturing device, a processing device, or a device, for example.

The sputtering device 1 is a device for performing magnetron sputtering, for example. The sputtering device 1 forms a film with metal particles on a surface of a semiconductor wafer 2, for example. The semiconductor wafer 2 is an example of an object and may also be referred to as a subject, for example. The sputtering device 1 may form a film on another subject, for example.

The sputtering device 1 includes a chamber 11, a target 12, a stage 13, a magnet 14, a shielding member 15, a collimator 16, a pump 17, and a tank 18. The target 12 is an example of a particle source. The collimator 16 may also be referred to as a shielding part, a flow rectifying part, or a direction adjusting part, for example.

As illustrated in the drawings, in the present specification, an X axis, a Y axis, and a Z axis are defined. The X axis, the Y axis, and the Z axis are orthogonal to one another. The X axis is along the width of the chamber 11. The Y axis is along the depth (length) of the chamber 11. The Z axis is along the height of the chamber 11. The following description will be given on the assumption that the Z axis is along a vertical direction. Note that the Z axis of the sputtering device 1 may obliquely intersect with the vertical direction.

The chamber 11 is formed in a sealable box shape. The chamber 11 includes an upper wall 21, a bottom wall 22, a side wall 23, a discharge port 24, and an introduction port 25. The upper wall 21 may also be referred to as, for example, a backing plate, a mounting portion, or a holding portion.

The upper wall 21 and the bottom wall 22 are arranged to face each other in the direction along the Z axis (vertical direction). The upper wall 21 is positioned above the bottom wall 22 via a predetermined interval. The side wall 23 is formed in a cylindrical shape extending in the direction along the Z axis, and connects the upper wall 21 and the bottom wall 22.

A processing chamber 11a is provided inside the chamber 11. The processing chamber 11a may also be referred to as an interior of a container. Inner walls of the upper wall 21, the bottom wall 22, and the side wall 23 form the processing chamber 11a. The processing chamber 11a can be airtightly closed. In other words, the processing chamber 11a can be hermetically sealed. The airtightly closed state is a state in which gas movement does not occur between an inside and an outside of the processing chamber 11a. The discharge port 24 and the introduction port 25 may open in the processing chamber 11a.

The target 12, the stage 13, the shielding member 15, and the collimator 16 are arranged in the processing chamber 11a. In other words, the target 12, the stage 13, the shielding member 15, and the collimator 16 are housed in the chamber 11. The target 12, the stage 13, the shielding member 15, and the collimator 16 may be partially positioned outside the processing chamber 11a.

The discharge port 24 opens into the processing chamber 11a and is connected to the pump 17. The pump 17 is, for example, a dry pump, a cryopump, a turbomolecular pump, or the like. As the pump 17 sucks a gas in the processing chamber 11a through the discharge port 24, the atmospheric pressure in the processing chamber 11a can be decreased. The pump 17 is capable of evacuating the processing chamber 11a.

The introduction port 25 opens into the processing chamber 11a and is connected to the tank 18. The tank 18 stores an inert gas such as an argon gas. The argon gas can be introduced from the tank 18 through the introduction port 25 into the processing chamber 11a. The tank 18 includes a valve capable of stopping the introduction of the argon gas.

The target 12 is, for example, a disc-shaped metal plate used as a particle source. Note that the target 12 may be formed in another shape. In the present embodiment, the target 12 is made of, for example, copper. The target 12 may be made of other materials.

The target 12 is attached to an attaching surface 21a of the upper wall 21 of the chamber 11. The upper wall 21 that is a backing plate is used as a coolant and an electrode of the target 12. The chamber 11 may include a backing plate as a separate part from the upper wall 21.

The attaching surface 21a of the upper wall 21 is an inner surface of the upper wall 21, the inner surface facing a negative direction (downward direction) along the Z axis and being formed to be approximately flat. The target 12 is arranged on such an attaching surface 21a. The upper wall 21 is an example of a source placement unit. The source placement unit is not limited to an independent member or part, and may be a specific position on a certain member or part.

The negative direction along the Z axis is an opposite direction to the direction to which the arrow of the Z axis points. The negative direction along the Z axis is a direction from the attaching surface 21a of the upper wall 21 to a placing surface 13a of the stage 13 and is an example of a first direction. The direction along the Z axis and the vertical direction include the negative direction along the Z axis and a positive direction along the Z axis (a direction to which the arrow of the Z axis points).

The target 12 includes a lower surface 12a. The lower surface 12a is an approximately flat surface facing downward. When a voltage is applied to the target 12, the argon gas introduced into the chamber 11 is ionized and plasma P is generated. FIG. 1 illustrates the plasma P by the two-dot chain line.

The magnet 14 is positioned outside the processing chamber 11a. The magnet 14 is, for example, an electromagnet or a permanent magnet. The magnet 14 is movable along the upper wall 21 and the target 12. The upper wall 21 is positioned between the target 12 and the magnet 14. The plasma P is generated near the magnet 14. Therefore, the target 12 is positioned between the magnet 14 and the plasma P.

When the argon ions of the plasma P collide with the target 12, particles C1 of a film forming material that configures the target 12 fly from the lower surface 12a of the target 12. In other words, the target 12 can eject the particles C1. In the present embodiment, the particles C1 contains copper ions, copper atoms, and copper molecules. The copper ions contained in the particles C1 has a positive charge. The copper atoms and copper molecules may have a positive or negative charge.

The directions into which the particles C1 fly from the lower surface 12a of the target 12 are distributed according to the cosine law (Lambert's cosine law). That is, the particles C1 that fly from a certain point on the lower surface 12a fly in a normal direction (vertical direction) of the lower surface 12a the most. The number of particles flying in a direction tilted with respect to (a direction obliquely intersecting with) the normal direction at an angle θ is approximately proportional to the cosine (cos θ) of the number of particles flying in the normal direction.

The particle C1 is an example of a particle in the present embodiment, and is a fine particle of the film forming material that configures the target 12. The particles may be various particles that make up a substance or energy rays, such as molecules, atoms, ions, nuclei, electrons, elementary particles, vapor (vaporized substance), and electromagnetic waves (photons).

The stage 13 is arranged on the bottom wall 22 of the chamber 11. The stage 13 is arranged away from the upper wall 21 and the target 12 in the direction along the Z axis. The stage 13 includes the placing surface 13a. The placing surface 13a of the stage 13 supports a semiconductor wafer 2. The semiconductor wafer 2 is formed in, for example, a disk shape. Note that the semiconductor wafer 2 may be formed in other shapes.

The placing surface 13a of the stage 13 is a substantially flat surface facing upward. The placing surface 13a is arranged away from the attaching surface 21a of the upper wall 21 in the direction along the Z axis and faces the attaching surface 21a. The semiconductor wafer 2 is arranged on such a placing surface 13a. The stage 13 is an example of an object placement unit. The object placement unit is not limited to an independent member or part, and may be a specific position on a certain member or part.

The stage 13 is movable in the direction along the Z axis, that is, in the vertical direction. The stage 13 includes a heater and is capable of warming the semiconductor wafer 2 arranged on the placing surface 13a. Further, the stage 13 is also used as an electrode.

The shielding member 15 is formed in an approximately cylindrical shape. The shielding member 15 covers a part of the side wall 23 and a gap between the side wall 23 and the semiconductor wafer 2. The shielding member 15 may hold the semiconductor wafer 2. The shielding member 15 suppresses adhesion of the particles C1 ejected from the target 12 to the bottom wall 22 and the side wall 23.

The collimator 16 is arranged between the attaching surface 21a of the upper wall 21 and the placing surface 13a of the stage 13 in the direction along the Z axis. According to another expression, the collimator 16 is arranged between the target 12 and the semiconductor wafer 2 in the direction along the Z axis (vertical direction). The collimator 16 is attached to the side wall 23 of the chamber 11, for example. The collimator 16 may be supported by the shielding member 15.

The collimator 16 and the chamber 11 are insulated. For example, an insulating member is interposed between the collimator 16 and the chamber 11. Further, the collimator 16 and the shielding member 15 are also insulated.

In the direction along the Z axis, the distance between the collimator 16 and the attaching surface 21a of the upper wall 21 is shorter than the distance between the collimator 16 and the placing surface 13a of the stage 13. In other words, the collimator 16 is closer to the attaching surface 21a of the upper wall 21 than to the placing surface 13a of the stage 13. The arrangement of the collimator 16 is not limited thereto.

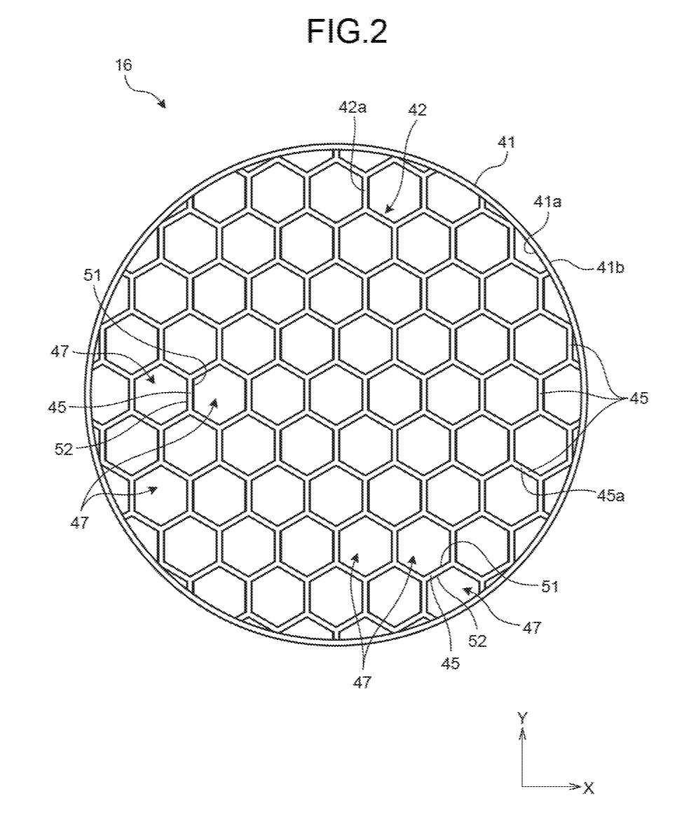

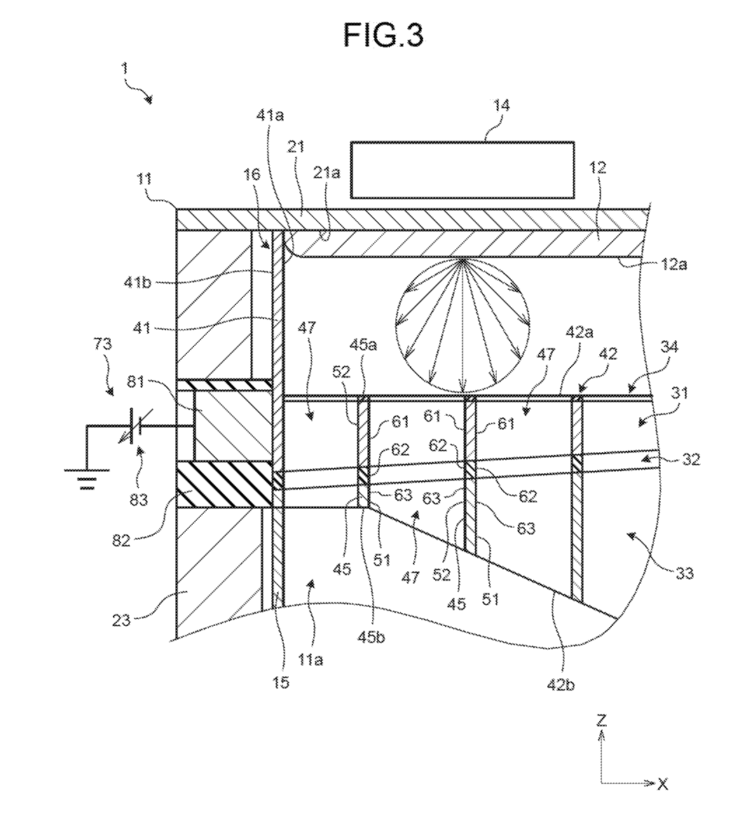

FIG. 2 is a plan view illustrating the collimator 16 of the first embodiment. FIG. 3 is a cross-sectional view illustrating a part of the sputtering device 1 of the first embodiment. As illustrated in FIG. 3, the collimator 16 is formed by a plurality of portions made of different materials.

In the present embodiment, the collimator 16 includes a first metal portion 31, a first insulating portion 32, a second metal portion 33, and a second insulating portion 34. The first metal portion 31 is an example of a first member. The first insulating portion 32 is an example of a second member. The second insulating portion 34 is an example of a fourth portion. The collimator 16 may include other portions.

The first metal portion 31 is made of the same material as the material of the target 12. In the present embodiment, the first metal portion 31 is made of copper. Copper is an example of a first material. Therefore, the first metal portion 31 has conductivity. The first metal portion 31 may be made of another material.

The first insulating portion 32 is made of a material different from the first metal portion 31. In the present embodiment, the first insulating portion 32 is made of a ceramic that is a material having insulating properties. The ceramic is an example of a second material. The first insulating portion 32 may be made of another material.

The first insulating portion 32 is arranged with the first metal portion 31 in the direction along the Z axis. In the direction along the Z axis, the first insulating portion 32 is closer to the stage 13 than the first metal portion 31 is. In other words, in the direction along the Z axis, the first insulating portion 32 is positioned between the first metal portion 31 and the stage 13.

The second metal portion 33 is made of a material different from the first metal portion 31. In the present embodiment, the second metal portion 33 is made of aluminum. Aluminum is an example of a third material. Therefore, the second metal portion 33 has conductivity. The density of aluminum is lower than that of the ceramic. The second metal portion 33 may be made of another material.

The second metal portion 33 is arranged with the first insulating portion 32 in the direction along the Z axis. In the direction along the Z axis, the second metal portion 33 is closer to the stage 13 than the first insulating portion 32 is. In the direction along the Z axis, the first insulating portion 32 is positioned between the first metal portion 31 and the second metal portion 33.

The second insulating portion 34 is made of a material different from the first metal portion 31. In the present embodiment, the second insulating portion 34 is made of a ceramic that is a material having insulating properties. The ceramic is an example of a fourth material. The second insulating portion 34 may be made of another material.

The collimator 16 formed by the first metal portion 31, the first insulating portion 32, the second metal portion 33, and the second insulating portion 34 includes a frame 41 and a flow rectifying portion 42. The frame 41 may also be referred to as, for example, an outer edge portion, a holding portion, a support portion, or a wall.

The first metal portion 31, the first insulating portion 32, and the second metal portion 33 configure a part of the frame 41 and a part of the flow rectifying portion 42. The second insulating portion 34 configures a part of the flow rectifying portion 42. In other words, the frame 41 and the flow rectifying portion 42 are formed by the first metal portion 31, the first insulating portion 32, the second metal portion 33, and the second insulating portion 34.

The frame 41 is a wall formed in a cylindrical shape extending in the direction along the Z axis. The frame 41 is not limited thereto, and may be formed in another shape such as a rectangle. The frame 41 includes an inner peripheral surface 41a and an outer peripheral surface 41b.

The inner peripheral surface 41a of the frame 41 is a curved surface that faces a radial direction of the cylindrical frame 41 and faces a central axis of the cylindrical frame 41. The outer peripheral surface 41b is positioned on an opposite side of the inner peripheral surface 41a. In an X-Y plane, the area of a portion surrounded by the outer peripheral surface 41b of the frame 41 is larger than the sectional area of the semiconductor wafer 2.

As illustrated in FIG. 1, the frame 41 covers a part of the side wall 23. The side wall 23 is covered with the shielding member 15 and the frame 41 of the collimator 16 between the upper wall 21 and the stage 13 in the direction along the Z axis. The frame 41 prevents adhesion of the particles C1 ejected front the target 12 to the side wall 23.

As illustrated in FIG. 2, the flow rectifying portion 42 is provided inside the cylindrical frame 41 on the X-Y plane. The flow rectifying portion 42 is connected to the inner peripheral surface 41a of the frame 41. The frame 41 and the flow rectifying portion 42 are integrally formed. The flow rectifying portion 42 may be an independent part of the frame 41.

As illustrated in FIG. 1, the flow rectifying portion 42 is arranged between the attaching surface 21a of the upper wall 21 and the placing surface 13a of the stage 13. The flow rectifying portion 42 is separated from the upper wall 21 and is separated from the stage 13 in the direction along the Z axis. As illustrated in FIG. 2, the flow rectifying portion 42 includes a plurality of walls 45. The wall 45 may also be referred to as, for example, a plate or a shielding portion.

The flow rectifying portion 42 forms a plurality of through holes 47 by the plurality of walls 45. Each of the plurality of through holes 47 is a hexagonal hole extending in the direction (vertical direction) along the Z axis. In other words, the plurality of walls 45 form an assembly of a plurality of hexagonal cylinders (honeycomb structure) having the through holes 47 formed therein. The through hole 47 extending in the direction along the Z axis can allow an object such as the particles C1 moving in the direction along the Z axis to pass therethrough. Note that the through hole 47 may be formed in another shape.

As illustrated in FIG. 3, parts of the plurality of walls 45 formed by the first metal portion 31 are integrally formed and connected to one another. Parts of the plurality of walls 45 formed by the first metal portion 31 are connected to a part of the frame 41 formed by the first metal portion 31.

Parts of the plurality of walls 45 formed by the first insulating portion 32 are integrally formed and connected to one another. Parts of the plurality of walls 45 formed by the first insulating portion 32 are connected to a part of the frame 41 formed by the first insulating portion 32.

Parts of the plurality of walls 45 formed by the second metal portion 33 are integrally formed and connected to one another. Parts of the plurality of walls 45 formed by the second metal portion 33 are connected to a part of the frame 41 formed by the second metal portion 33.

Parts of the plurality of walls 45 formed by the second insulating portion 34 are integrally formed and connected to one another. Parts of the plurality of walls 45 formed by the second insulating portion 34 is connected to a part of the frame 41 formed by the first metal portion 31.

The flow rectifying portion 42 includes an upper end portion 42a and a lower end portion 42b. The upper end portion 42a is one end portion of the flow rectifying portion 42 in the direction along the Z axis and faces the target 12 and the attaching surface 21a of the upper wall 21. The lower end portion 42b is the other end portion of the flow rectifying portion 42 in the direction along the Z and faces the semiconductor wafer 2 supported by the stage 13 and the placing surface 13a of the stage 13.

The through hole 47 is provided from the upper end portion 42a to the lower end portion 42b of the flow rectifying portion 42. That is, the through hole 47 is a hole that opens toward the target 12 and opens toward the semiconductor wafer 2 supported by the stage 13.

Each of the plurality of walls 45 is a substantially rectangular (quadrangular) plate extending in the direction along the Z axis. The wall 45 may extend in a direction obliquely intersecting with the direction along the Z axis, for example. The wall 45 includes an upper end surface 45a and a lower end surface 45b. The upper end surface 45a is an example of an end portion.

The upper end surface 45a of the wall 45 is one end portion in the direction along the Z axis of the wall 45 and faces the target 12 and the attaching surface 21a of the upper wall 21. The upper end surface 45a of the plurality of walls 45 forms the upper end portion 42a of the flow rectifying portion 42.

The upper end portion 42a of the flow rectifying portion 42 is formed to be substantially flat. The upper end portion 42a may foe recessed in a curved manner with respect to the target 12 and the attaching surface 21a of the upper wall 21, for example. In other words, the upper end portion 42a may foe curved away from the target 12 and the attaching surface 21a of the upper wall 21.

The lower end surface 45b of the wall 45 is the other end portion in the direction along the Z axis of the wall 45 and faces the semiconductor wafer 2 supported by the stage 13 and the placing surface 13a of the stage 13. The lower end surface 45b of the plurality of walls 45 forms the lower end portion 42b of the flow rectifying portion 42.

The lower end portion 42b of the flow rectifying portion 42 protrudes toward the semiconductor wafer 2 supported by the stage 13 and the placing surface 13a of the stage 13. In other words, the lower end portion 42b of the flow rectifying portion 42 approaches the stage 13 as the lower end portion 42b is away from the frame 41. The lower end portion 42b of the flow rectifying portion 42 may be formed in another shape.

The upper end portion 42a and the lower end portion 42b of the flow rectifying portion 42 have different shapes from each other. Therefore, the flow rectifying portion 42 includes the plurality of walls 45 having different lengths in the vertical direction. Note that, in the direction along the Z axis, the lengths of the plurality of walls 45 may be the same.

Each of the plurality of walls 45 includes a first inner surface 51 and a second inner surface 52. The first inner surface 51 and the second inner surface 52 face a direction orthogonal to the Z axis (direction on the X-Y plane). The second inner surface 52 is positioned on the opposite side of the first inner surface 51.

The first inner surface 51 of one wall 45 faces one through hole 47 formed by the wall 45. The second inner surface 52 of the wall 45 faces another through hole 47 formed by the wall 45. In the present embodiment, six of the first inner surfaces 51 and the second inner surfaces 52 of the plurality of walls 45 define one through hole 47.

For example, three first inner surfaces 51 and three second inner surfaces 52 define one through hole 47. In this example, the three first inner surfaces 51 and the three second inner surfaces 52 face the through hole 47.

In the present embodiment, the first inner surface 51 faces the center axis of the frame 41 in the radial direction of the frame 41. In other words, the first inner surface 51 faces the inside of the frame 41. The second inner surface 52 faces the outside of the frame 41. The first inner surface 51 and the second inner surface 52 may face other directions.

The first inner surface 51 includes a first portion 61, a second portion 62, and a third portion 63. Further, the second inner surface 52 also includes a first portion 61, a second portion 62, and a third portion 63.

The first portions 61 are parts of the first inner surface 51 and the second inner surface 52 formed by the first metal portion 31. In other words, the first metal portion 31 configures the first portions 61. Therefore, the first portion 61 is made of copper and has conductivity.

The second portions 62 are parts of the first inner surface 51 and the second inner surface 52 formed by the first insulating portion 32. In other words, the first insulating portion 32 configures the second portions 62. Therefore, the second portion 62 is made of the ceramic and has insulating properties. The second portion 62 is arranged with the first portion 61 in the direction along the Z axis and is closer to the stage 13 than the first portion 61 is.

The third portions 63 are parts of the first inner surface 51 and the second inner surface 52 formed by the second metal portion 33. In other words, the second metal portion 33 configures the third portions 63. Therefore, the third portion 63 is made of aluminum and has conductivity. The third portion 62 is arranged with the second portion 62 in the direction along the Z axis and is closer to the stage 13 than the second portion 62 is. The second portion 62 is positioned between the first portion 61 and the third portion 63 in the direction along the Z axis.

In the direction along the Z axis, the length of the first portion 61 in one of the plurality of walls 45 is longer than the length of the first portion 61 in another one of the plurality of walls 45. In the present embodiment, the first portion 61 becomes longer as the first portion 61 approaches the frame 41 from the center axis of the frame 41. For example, in the direction along the Z axis, the length of the first portion 61 of one wall 45 is shorter than the length of the first portion 61 of the wall 45 closer to the frame 41 than the aforementioned one wall 45. In other words, the length of the first portion 61 of the inner wall 45 is shorter than the length of the first portion 61 of the outer wall 45.

In the direction along the Z axis, the lengths of the second portions 62 of the plurality of walls 45 are approximately equal. Further, in the direction along the Z axis, the lengths of the third portions 63 of the plurality of walls 45 are different from one another. For example, in the direction along the Z axis, the length of the third portion 63 of one wall 45 is longer than the length of the third portion 63 of the wall 45 closer to the frame 41 than the aforementioned one wall 45. The lengths of the first to third portions 61 to 63 are not limited thereto.

The second insulating portion 34 forms the upper end surface 45a of the wall 45. Therefore, the first metal portion 31 is positioned between the second insulating portion 34 and the first insulating portion 32. In other words, the first portion 61 is positioned between the second insulating portion 34 and the second portion 62.

As illustrated in FIG. 1, the sputtering device 1 further includes a first power supply device 71, a second power supply device 72, and a third power supply device 73. The third power supply device 73 is an example of a power supply.

The first power supply device 71 and the second power supply device 72 are DC variable power supplies. Note that the first power supply device 71 and the second power supply device 72 may be other power supplies. The first power supply device 71 is connected to the upper wall 21 that is an electrode. The first power supply device 71 can apply, for example, a negative voltage to the upper wall 21 and the target 12. The second power supply device 72 is connected to the stage 13 that is an electrode. The second power supply device 72 can apply, for example, a negative voltage to the stage 13 and the semiconductor wafer 2.

As illustrated in FIG. 3, the third power supply device 73 includes an electrode 81, an insulating member 82, and a power supply 83. The electrode 81 and the insulating member 82 are provided on the side wall 23 of the chamber 11. The collimator 16 faces the electrode 81. The arrangement of the electrodes 81 is not limited thereto.

The electrode 81 is in contact with a part of the outer peripheral surface 41b of the frame 41 formed by the first metal portion 31. The electrode 81 is pushed toward the part of the outer peripheral surface 41b of the frame 41 formed by the first metal portion 31 by, for example, a spring. The electrode 81 electrically connects the first metal portion 31 and the power supply 83.

The insulating member 82 is made of an insulating material such as a ceramic. The insulating member 82 surrounds the electrode 81 in a manner that the electrode 81 is movable. The insulating member 82 insulates the electrode 81 from the side wall 23 of the chamber 11.

The power supply 83 is a DC variable power supply. The power supply 83 may be another power supply. The power supply 83 is electrically connected to the first metal portion 31 via the electrode 81. The power supply 83 can apply a negative voltage to the first metal portion 31. In other words, the power supply 83 can apply a negative voltage to the first portions 61 of the first and second inner surfaces 51 and 52. Note that the power supply 83 may be able to apply a positive voltage to the first portions 61.

The sputtering device 1 described above performs magnetron sputtering, as follows, for example. A method of performing magnetron sputtering by the sputtering device 1 is not limited to the method described below.

First, the pump 17 illustrated in FIG. 1 sucks the gas in the processing chamber 11a through the discharge port 24. As a result, the air in the processing chamber 11a is removed, and the atmospheric pressure in the processing chamber 11a is reduced. The pump 17 evacuates the processing chamber 11a.

Next, the tank 18 allows an argon gas to be introduced into the processing chamber 11a through the introduction port 25. When the first power supply device 71 applies a voltage to the target 12, the plasma P is generated near a magnetic field of the magnet 14. Further, the second power supply device 72 may apply a voltage to the stage 13.

When ions sputter the lower surface 12a of the target 12, the particles C1 are ejected from the lower surface 12a of the target 12 toward the semiconductor wafer 2. In this embodiment, the particles C1 contain copper ions. The copper ions have a positive charge. As described above, the directions into which the particles C1 fly are distributed according to the cosine law. The arrows in FIG. 3 schematically illustrate the distribution of the directions into which the particles C1 fly.

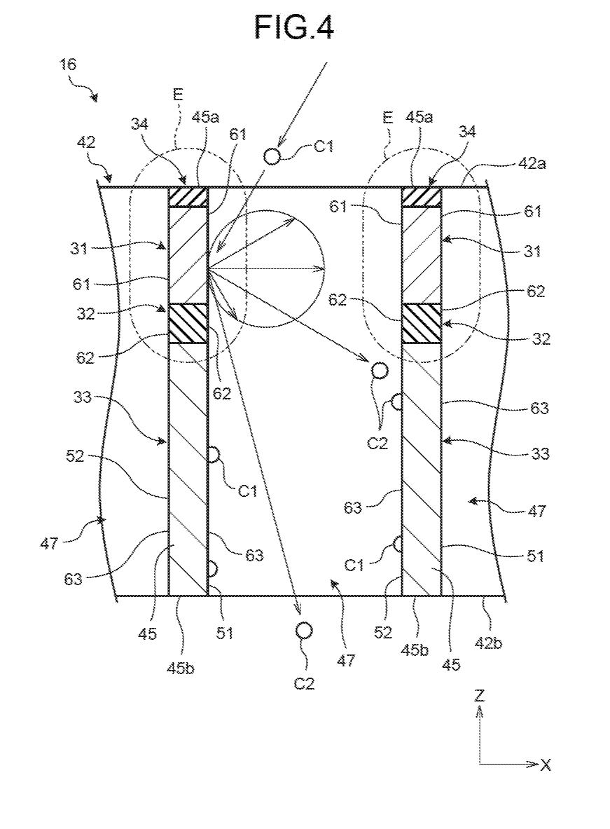

FIG. 4 is a cross-sectional view schematically illustrating a part of the collimator 16 of the first embodiment. The power supply 83 applies a negative voltage to the first metal portion 31. That is, the power supply 83 applies a voltage having a polarity different from a polarity of an electric charge in the copper ions that are the particles C1, to the first portion 61 formed by the first metal portion 31.

The first metal portion 31 that forms the first portion 61 to which a negative voltage has been applied generates an electric field E. That is, a part of the frame 41 formed by the first metal portion 31 and a part of the wall 45 generate the electric field E.

The first insulating portion 32 is positioned between the first metal portion 31 and the second metal portion 33. In other words, the first insulating portion 32 insulates the first metal portion 31 from the second metal portion 33. Therefore, when a voltage is applied to the first metal portion 31, the second metal portion 33 does not generate an electric field.

The particles C1 ejected in the vertical direction pass through the through hole 47 and fly toward the semiconductor wafer 2 supported by the stage 13. On the other hand, there are also the particles C1 ejected in a direction obliquely intersecting with the vertical direction (in an inclined direction). The particles C1 having an angle larger than a predetermined range, the angle being made by the inclined direction and the vertical direction, fly toward the wall 45.

The particles C1, which are positively charged ions, are attracted by the electric field E generated by the first metal portion 31 to which the negative voltage has been applied. For this reason, the particles C1 approaching the first metal portion 31 that generates the electric field E are accelerated toward the first portion 61. In other words, the electric field E imparts kinetic energy toward the first portion 61 to the particles C1.

The accelerated particles C1 collide with the first portion 61. In other words, the particles C1, which are ions, sputter the first portion 61. As a result, particles C2 are ejected from the first portion 61.

The particles C2 ejected from the first portion 61 include copper ions, copper atoms, and copper molecules, like the particles C1 ejected from the target 12. In this way, the first portion 61 can eject the particles C2 that are the same as the particles C1 ejected by the target 12. Since the particles C1 adhere to the first portion 61 that ejects the particles C2, a decrease in the volume of the first metal portion 31 is suppressed.

Directions into which the particles C2 fly from the first portion 61 are distributed according to the cosine law. Therefore, the particles C2 ejected from the first portion 61 include particles C2 ejected in the vertical direction. The particles C2 ejected in the vertical direction pass through the through hole 47 and fly toward the semiconductor wafer 2 supported by the stage 13.

The particles C2 also include particles C2 ejected in a direction intersecting with the vertical direction. For example, the particles C2 may fly from the first portion 61 of one wall 45 toward the first inner surface 51 or the second inner surface 52 of another wall 45.

The particles C2 may fly toward the first portion 61 of another wall 45. The particles C2, which are ions, are accelerated by the electric field E and collide with the first portion 61 of another wall 45. The first portion 61 sputtered by the particles C2 may further elect the particles C2. However, for example, if the kinetic energy of the particles C2 that collide with the first portion 61 is not sufficient, the particles C2 adhere to the first portion 61.

The particles C2 may fly toward the second portion 62 or the third portion 63 of another wall 45. The first insulating portion 32 that forms the second portion 62 and the second metal portion 33 that forms the third portion 63 do not generate an electric field. Therefore, the particles C2 are not accelerated.

The particles C2 that fly toward the second portion 62 adhere to the second portion 62. The particles C2 that fly toward the third portion 63 adhere to the third portion 63. That is, the kinetic energy of the non-accelerated particles C2 is lower than the kinetic energy for causing particles to be elected from the third portion 63 by sputtering. The second portion 62 and the third portion 63 block the particles C2 having an angle that falls outside a predetermined range, the angle being made by a direction into which the particles C2 are ejected and the vertical direction.

The first portion 61 is closer to the upper wall 21 and the target 12 than the second portion 62 and the third portion 63 are. Therefore, the argon ions of the plasma P sometimes collide with the first portion 61. Even in a case where the argon ions sputter the first portion 61, the particles C2 are ejected from the first portion 61.

The particles C1 ejected from the target 12 may fly toward the upper end surface 45a of the wall 45. The second insulating portion 34 that forms the upper end surface 45a does not generate an electric field. Therefore, the particles C1 that fly toward the upper end surface 45a are not. accelerated and adhere to the upper end surface 45a.

The particles C1 ejected from the target 12 may contain copper atoms and copper molecules that are electrically neutral, The electric field E does not accelerate the electrically neutral particles C1. For this reason, the particles C1, which are electrically neutral and have an angle larger than a predetermined range, the angle being made by the inclined direction and the vertical direction, may adhere to the wall 45. That is, the collimator 16 blocks the particles C1 having an angle that falls outside a predetermined range, the angle being made by the inclined direction and the vertical direction. The particles C1 flying in the inclined direction may adhere to the shielding member 15.

The particles C1 having an angle that falls within a predetermined range, the angle being made by the inclined direction and the vertical direction, pass through the through hole 47 of the collimator 16 and fly toward the semiconductor wafer 2 supported by the stage 13. Note that the particles C1 having the angle that falls within a predetermined range, the angle being made by the inclined direction and the vertical direction, may also be attracted by the electric field E or adhere to the wall 45.

The particles C1 and C2 that have passed through the through hole 47 of the collimator 16 adhere to and are deposited on the semiconductor wafer 2, whereby a film is formed on the semiconductor wafer 2. In other words, the semiconductor wafer 2 receives the particles C1 ejected by the target 12 and the particles C2 ejected by the first portion 61. The directions of the particles C1 and C2 that have passed through the through hole 47 are adjusted within a predetermined range with respect to the vertical direction. In this way, the directions of the particles C1 and C2 deposited on the semiconductor wafer 2 are controlled according to the shape of the collimator 16.

The magnet 14 is moved until the thickness of the film of the particles C1 and C2 formed on the semiconductor wafer 2 reaches a desired thickness. As the magnet 14 is moved, the plasma P is moved and the target 12 can be Uniformly shaved.

The collimator 16 of the present embodiment is laminated and shaped by, for example, a 3D printer. Therefore, the collimator 16 having the first metal portion 31, the first insulating portion 32, the second metal portion 33, and the second insulating portion 34 can be easily manufactured. Note that the collimator 16 is not limited thereto, and may be manufactured by another method.

The first metal portion 31, the first insulating portion 32, the second metal portion 33, and the second insulating portion 34 of the collimator 16 are fixed to one another. That is, in the direction along the Z axis, one end portion of the first metal portion 31 is fixed to the second insulating portion 34, and the other end portion of the first metal portion 31 is fixed to the first insulating portion 32. Further, in the direction along the Z axis, one end portion of the first insulating portion 32 is fixed to the first metal portion 31, and the other end portion of the first insulating portion 32 is fixed to the second metal portion 33.

For example, the first metal portion 31, the first insulating portion 32, the second metal portion 33, and the second insulating portion 34 of the collimator 16 are integrally formed. The first metal portion 31, the first insulating portion 32, the second metal portion 33, and the second insulating portion 34 of the collimator 16 may be glued to one another, for example.

The first metal portion 31, the first insulating portion 32, the second metal portion 33, and the second insulating portion 34 of the collimator 16 may be separable from one another. For example, the first metal portion 31, the first insulating portion 32, the second metal portion 33, and the second insulating portion 34, which are independent parts, are stacked on one another. In this case, the first metal portion 31, the first insulating portion 32, the second metal portion 33, and the second insulating portion 34 can be easily manufactured.

In the sputtering device 1 according to the first embodiment, the first inner surface 51 of the collimator 16 includes the first portion 61 made of copper capable of ejecting the particles C2, and the second portion 62 made of a ceramic different from copper, and arranged with the first portion 61 in the direction along the Z axis and close to the stage 13 than the first portion 61 is. For example, when particles C1 ejected from the target 12 collide with the first portion 61, the particles C2 can be ejected from the first portion 61. Further, in sputtering, the plasma P generated near the upper wall 21 can generate the particles C2 from the first portion 61. When the particles C2 ejected from the first portion 61 are ejected in the direction along the Z axis, film formation is performed with the particles C2. That is, the particles C1 ejected in the inclined direction can generate the particles C2 ejected in the vertical direction. As a result, reduction in utilization efficiency of the particles C1 and C2 is suppressed.

The first portion 61 is closer to the upper wall 21 than the second portion 62 is. Therefore, even if the particles C2 ejected from the first portion 61 are ejected in a direction largely different from the direction along the Z axis, the second portion 62 and the third portion 63 block the particles C2. As a result, adhesion of the particles C1 ejected in the direction largely different from the direction along the Z axis to the semiconductor wafer 2 is suppressed, and a decrease in film forming performance of the collimator 16 is suppressed.

The third power supply device 73 applies a voltage having a polarity different from a polarity of an electric charge in the particles C1 ejected from the target 12, to the first portion 61. According to another expression, in the case where copper that is the material of the first portion 61 is ionized, the third power supply device 73 applies a voltage having a polarity different from a polarity of an electric charge of the ions, to the first portion 61. As a result, the electric field E generated by the first portion 61 causes an attractive force to act on the particles C1 ejected from the target 12. Since the particles C1 on which the attractive force has acted are accelerated, the particles C2 can be easily ejected from the first portion 61 when the particles C1 collide with the first portion 61. The particles C2 can be ejected toward the semiconductor wafer 2. Accordingly, a decrease in the utilization efficiency of the particles C1 and C2 is suppressed. Further, the ceramic that forms the second portion 62 has insulating properties. Therefore, attraction of the particles C1 ejected from the target 12 by the second portion 62 is suppressed, and the decrease in the utilization efficiency of the particles C1 and C2 is suppressed.

The first inner surface 51 includes the third portion 63 made of aluminum different from copper, and arranged with the second portion 62 in the direction along the Z axis and closer to the stage 13 than the second portion 62. In other words, the insulating second portion 62 lies between the first portion 61 and the third portion 63. With the configuration, application of the voltage to the third portion 63, the voltage having been applied to the first portion 61, is suppressed. Therefore, attraction of the particles C1 ejected front the target 12 by the third portion 63 is suppressed, and the decrease in the utilization efficiency of the particles C1 and C2 is suppressed. Further, generation of particles such as aluminum ions, aluminum atoms, and aluminum molecules from the third portion 63 is suppressed.

The density of aluminum that is the material of the third portion 63 is lower than the density of the ceramic that is the material of the second portion 62. Therefore, the collimator 16 can be made lighter than a case where the portion formed by the second metal portion 33 is formed by the first insulating portion 32 instead.

In the direction along the Z axis, the length of the first portion 61 in one of the plurality of walls 45 is longer than the length of the first portion 61 in another one of the plurality of walls 45. For example, the length of the first portion 61 of the wall 45, of an outer portion of the collimator 16, is set to be longer than the length of the first portion 61 of the wall 45, of an inner portion of the collimator 16. In one example, many particles C1 vertically fly toward the semiconductor wafer 2 in the inner portion of the collimator 16. On the other hand, a few particles C1 vertically fly toward the semiconductor wafer 2 in the outer portion of the collimator 16. However, there are many obliquely flying particles C1, which collide with the first portion 61 to eject the particles C2 at the first portion 61. Therefore, the number of the particles C1 and C2 that fly from the inner portion of the collimator 16 toward the semiconductor wafer 2 and the number of the particles C1 and C2 that fly from the outer portion of the collimator 16 toward the semiconductor wafer 2 are likely to become equal. Therefore, variation of the distribution of the particles C1 and C2 adhering to the semiconductor wafer 2 is suppressed.

The second insulating portion 34 that forms the upper end surface 45a of the wall 45 is made of an insulating ceramic different from copper. The particles C1 ejected from the target 12 may collide with the upper end surface 45a of the wall 45. However, since the second insulating portion 34 does not attract the particles C1, the particles C1 colliding with the upper end surface 45a are prevented from ejecting the particles from the upper end surface 45a. Therefore, interference by the particles ejected from the upper end surface 45a with the particles C1 ejected from the target 12 is suppressed.

The first metal portion 31 having the first portion 61 is fixed to the first insulating portion 32 having the second portion 62. With the configuration, the through hole 47 formed by the first metal portion 31 and the through hole 47 formed by the first insulating portion 32 are displaced, whereby the size of the through hole 47 is changed, and the decrease in the utilization efficiency of the particles C1 and C2 is suppressed.

As described above, the first metal portion 31 having the first portion 61 may be detachable from the first insulating portion 32 having the second portion 62. In this case, for example, the collimator 16 is formed by stacking the first metal portion 31 on the first insulating portion 32. With the configuration, the collimator 16 having the first metal portion 31 and the first insulating portion 32 can be easily manufactured.

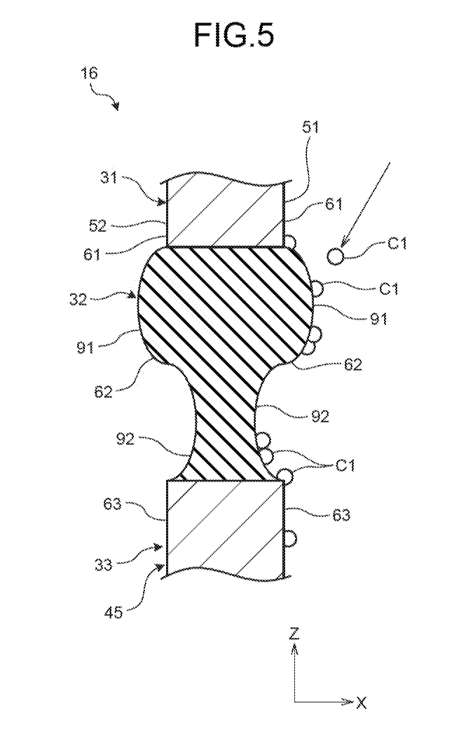

Hereinafter, a second embodiment will be described with reference to FIG. 5. Note that, in the description of a plurality of embodiments below, a configuration element having a similar function to the already described configuration element is denoted with the same reference signs as the already described configuration element, and description may be omitted. In addition, a plurality of configuration elements denoted with the same reference sign does not necessarily share all of the functions and characteristics, and may have different functions and characteristics according to the embodiments.

FIG. 5 is a cross-sectional view illustrating a part of a collimator 16 according to the second embodiment. As illustrated in FIG. 5, a second portion 62 forms a protruding portion 91 and a recessed portion 92. The second portion 62 may include only one of the protruding portion 91 and the recessed portion 92.

The protruding portion 91 protrudes from a first portion 61 arranged with the second portion 62 in a direction in which a first inner surface 51 of a wall 45 provided with the second portion 62 faces. The direction that the first inner surface 51 faces is an example of a second direction. The surface of the protruding portion 91 is a curved surface.

The recessed portion 92 is recessed from the first portion 61 arranged with the second portion 62 in the direction that the first inner surface 51 of the wall 45 provided with the second portion 62 faces. The surface of the recessed portion 92 is a curved surface.

The protruding portion 91 and the recessed portion 92 are smoothly connected to each other. In other words, the protruding portion 91 and the recessed portion 92 are continuous without forming an acute-angled portion. In a direction along a Z axis, the protruding portion 91 is closer to the first portion 61 than the recessed portion 92 is.

The particles C1 having an angle larger than a predetermined range, the angle being made by an inclined direction and a vertical direction, may adhere to the second portion 62. A portion of the protruding portion 91, the portion facing a stage 13, becomes shaded with respect to a target 12, and to which the particles C1 are difficult to adhere. A portion of the recessed portion 92, the portion facing the stage 13, becomes shaded with respect to the target 12, and to which the particles C1 are difficult to adhere.

In the sputtering device 1 of the second embodiment, the second portion 62 forms at least one of the protruding portion 91 protruding from the first portion 61 and the recessed portion 92 recessed from the first portion 61. In the case where the second portion 62 forms the protruding portion 91, the particles C1 ejected from the target 12 adhere to a portion of the protruding portion 91, the portion being close to the target 12, but are difficult to adhere to a portion of the protruding portion 91, the portion being distant from the target 12. In the case where the second portion 62 includes the recessed portion 92, the particles C1 ejected from the target 12 adhere to a portion of the recessed portion 92, the portion being distant from the target 12, but are difficult to adhere to a portion of the recessed portion 92, the portion being close to the target 12. In this manner, the portions to which the particles C1 are difficult to adhere are formed in the second portion 62. Therefore, conduction between the first portion 61 and the third portion 63 by the particles C1 is suppressed.

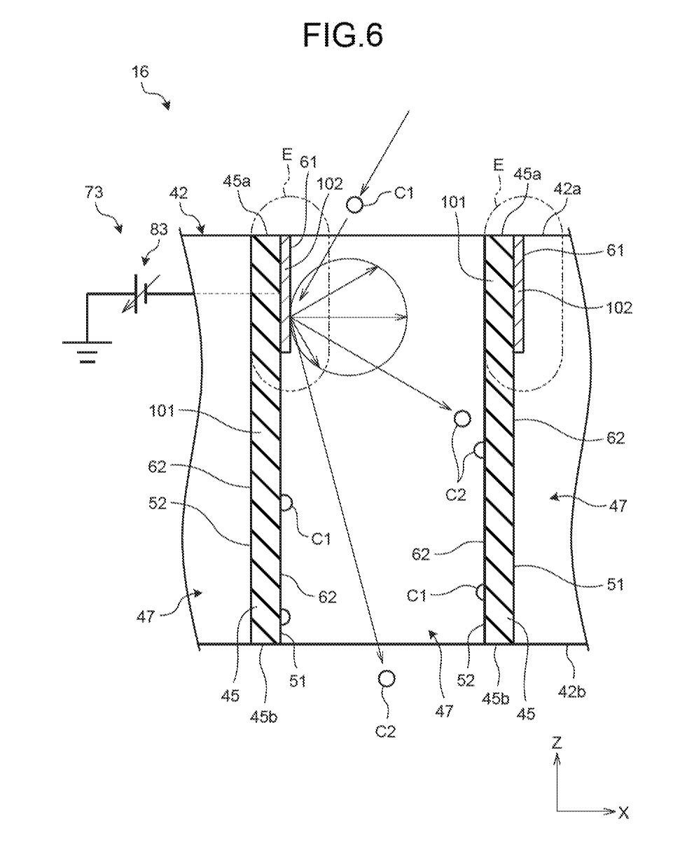

Hereinafter, a third embodiment will be described with reference to FIG. 6. FIG. 6 is a cross-sectional view schematically illustrating a part of a collimator 16 according to the third embodiment. As illustrated in FIG. 6, the collimator 16 of the third embodiment includes a member 101 and a plurality of metal portions 102, in place of the first metal portion 31, the first insulating portion 32, the second metal portion 33, and the second insulating portion 34.

The member 101 is made of a ceramic which is an insulating material. The member 101 may be made of another material. The member 101 includes a frame 41 and a flow rectifying portion 42. Therefore, the member 101 includes a plurality of walls 45.

A first inner surface 51 of the wall 45 includes a first portion 61 and a second portion 62. The member 101 forms the second portion 62. That is, the second portion 62 is made of the ceramic and has insulating properties. As in the first embodiment, the second portion 62 is closer to the stage 13 than the first portion 61 is.

The metal portion 102 is made of the same material as the target 12. In the present embodiment, the metal portion 102 is made of copper. Therefore, the metal portion 102 has conductivity. The metal portion 102 may be made of another material.

In the present embodiment, the metal portion 102 is a metal film. The metal portion 102 may be, for example, a wall, a plate, or another member. The metal portion 102 covers a part of a surface of the member 101 and forms the first portion 61.

For the purpose of illustration, FIG. 6 illustrates that the metal portion 102 protrudes from the surface of the member 101. However, the first portion 61 formed by the metal portion 102 and the second portion 62 formed by the member 101 form the substantially continuous first inner surface 51.

A power supply 83 of a third power supply device 73 is electrically connected to the metal portion 102. For example, wiring that passes through insides of the plurality of walls 45 electrically connects the metal portion 102 and the power supply 83. The power supply 83 can apply a negative voltage to the first portion 61 formed by the metal portion 102.

The first inner surface 51 includes the first portion 61 and the second portion 62 but a second inner surface 52 includes the second portion 62, of the first and second portions 61 and 62, and does not include the first portion 61. That is, the second inner surface 52 of the wall 45 is formed by the member 101 having the second portion 62. Further, an upper end surface 45a and a lower end surface 45b of the wall 45 are also formed by the member 101.

Note that the second inner surface 52 may include the first portion 61. In this case, the metal portion 102 forms the first portion 61, like the first inner surface 51. In a direction along a z axis, the length of the first portion 61 of the first inner surface 51 and the length of the second portion 61 of the second inner surface 51 may be different from each other.

In such a sputtering device 1, ions of plasma P sputter a lower surface 12a of the target 12, whereby particles C1 are ejected from the lower surface 12a of the target 12 toward a semiconductor wafer 2.

The power supply 83 applies a negative voltage to the metal portion 102. That is, the power supply 83 applies a voltage having a polarity different from a polarity of an electric charge in copper ions that are the particles C1, to the first portion 61 formed by the metal portion 102. The metal portion 102 that forms the first portion 61 to which the negative voltage has been applied generates an electric field E.

The member 101 that forms the second portion 62 has insulating properties. Therefore, when a voltage is applied to the metal portion 102, the member 101 that forms the second portion 62 does not generate an electric field.

The particles C1 having an angle larger than a predetermined range, the angle being made by the inclined direction and the vertical direction, fly toward the wall 45. The particles C1, which are positively charged ions, are attracted by the electric field E generated by the metal portion 102 to which the negative voltage has been applied. Therefore, the particles C1 approaching the metal portion 102 that generates the electric field E are accelerated toward the first portion 61.

The accelerated particles C1 collide with the first portion 61. In other words, the particles C1, which are ions, sputter the first portion 61. As a result, particles C2 are ejected from the first portion 61.

The particles C2 ejected from the first portion 61 include copper ions, copper atoms, and copper molecules, like the particles C1 ejected from the target 12. In this way, the first portion 61 can eject the particles C2 that are the same as the particles C1 ejected by the target 12. Since the particles C1 adhere to the first portion 61 that ejects the particles C2, a decrease in the volume of the metal portion 102 is suppressed.

Directions into which the particles C2 fly from the first portion 61 are distributed according to the cosine law. Therefore, the particles C2 ejected from the first portion 61 include particles C2 ejected in the vertical direction. The particles C2 ejected in the vertical direction pass through a through hole 47 and fly toward the semiconductor wafer 2 supported by the stage 13.

The particles C2 also include particles C2 ejected in a direction intersecting with the vertical direction. For example, the particles C2 may fly from the first portion 61 of one wall 45 toward the first inner surface 51 or the second inner surface 52 of another wall 45.

The particles C2 may fly toward the first portion 61 of another wall 45. The particles C2, which are ions, are accelerated by the electric field E and collide with the first portion 61 of another wall 45. The first portion 61 sputtered by the particles C2 may further eject the particles C2. However, for example, if the kinetic energy of the particles C2 that collide with the first portion 61 is not sufficient, the particles C2 adhere to the first portion 61.

The particles C2 may fly toward the second portion 62 of another wall 45. The member 101 that forms the second portion 62 does not generate an electric field. Therefore, the particles C2 are not accelerated. The particles C2 that fly toward the second portion 62 adhere to the second portion 62. The second portion 62 blocks the particles C2 having an angle that falls outside a predetermined range, the angle being made by the direction into which the particles C2 are ejected and the vertical direction.

The first portion 61 is closer to an tipper wall 21 and the target 12 than the second portion 62 is. Therefore, argon ions of the plasma P sometimes collide with the first portion 61. Even in a case where the argon ions sputter the first portion 61, the particles C2 are ejected from the first portion 61.

The particles C1 and C2 that have passed through the through hole 47 of the collimator 16 adhere to and are deposited on the semiconductor wafer 2, whereby a film is formed on the semiconductor wafer 2. In other words, the semiconductor wafer 2 receives the particles C1 ejected by the target 12 and the particles C2 ejected by the first portion 61. The directions of the particles C1 and C2 that have passed through the through hole 47 are adjusted within a predetermined range with respect to the vertical direction. In this way, the directions of the particles C1 and C2 deposited on the semiconductor wafer 2 are controlled according to the shape of the collimator 16.

In the sputtering device 1 of the third embodiment, the second inner surfaces 52 of the plurality of walls 45 include the second portions 62 and do not include the first portions 61. That is, one surface 51 of the wall 45 generates the particles C2 from the first portion 61, while the other surface 52 of the wall 45 does not generate the particles C2. Such a wall 45 is provided, whereby distribution of the particles C1 and C2 that adhere to the semiconductor wafer 2 can be adjusted.

According to at least one embodiment described above, the first inner surface of the collimator includes the first portion made of the first material capable of ejecting the particles and the second portion made of the second material different from the first material, and arranged with the first portion in the first direction and closer to an object placement unit than the first portion. With the configuration, a decrease in the utilization efficiency of the particles is suppressed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A processing device comprising:
an object placement unit configured to have an object placed thereon;
a source placement unit arranged apart from the object placement unit and configured to have a particle source placed thereon, the particle source being capable of ejecting a particle toward the object; and
a collimator configured to be arranged between the object placement unit and the source placement unit, including a plurality of walls, and provided with a plurality of through holes formed by the plurality of walls and extending in a first direction from the source placement unit to the object placement unit, wherein
the plurality of walls include a first inner surface facing the through hole, and
the first inner surface includes a first portion made of a first material capable of ejecting the particle, and a second portion made of a second material different from the first material, and arranged with the first portion in the first direction and closer to the object placement unit than the first portion.

2. The processing device according to claim 1, further comprising:
a power supply configured to apply, to the first portion, a voltage having a polarity different from a polarity of an electric charge in the particle ejected from the particle source, wherein
the second material has an insulating property.

3. The processing device according to claim 2, wherein the first inner surface includes a third portion made of a conductive third material different from the first material, and arranged with the second portion in the first direction and closer to the object placement unit than the second portion.

4. The processing device according to claim 3, wherein
the second portion forms at least one of a protruding portion protruding from the first portion in a second direction that the first inner surface faces, and a recessed portion recessed from the first portion in the second direction.

5. The processing device according to claim 1, wherein
a length of the first portion in one of the plurality of walls is longer than a length of the first portion in another one of the plurality of walls, in the first direction.

6. The processing device according to claim 1, wherein
the plurality of walls include a second inner surface positioned on an opposite side of the first inner surface, and
the second inner surface includes the second portion.

7. The processing device according to claim 1, wherein
the plurality of walls include an end portion in the first direction and a fourth portion made of an insulating fourth material different from the first material, the end portion facing the source placement unit, and the fourth portion forming the end portion.

8. The processing device according to claim 1, wherein the collimator includes a first member made of the first material and including the first portion, and a second member made of the second material, including the second portion, and arranged with the first member in the first direction, and
the first member is fixed to the second member.

9. The processing device according to claim 1, wherein
the collimator includes a first member made of the first material and including the first portion, and a second member made of the second material, including the second portion, and arranged with the first member in the first direction, and
the first member is separable from the second member.

10. A collimator comprising:
a plurality of walls forming a plurality of through holes extending in a first direction;
a first inner surface provided in the plurality of walls and facing the through hole;
a first portion made of a first material capable of ejecting particle, and forming a part of the first inner surface; and
a second portion made of a second material different from the first material, forming a part of the first inner surface, and arranged with the first portion in the first direction.

11. The collimator according to claim 10, wherein
the first material has conductivity, and
the second material has an insulating property.

12. The collimator according to claim 11, further comprising:
a third portion made of a conductive third material different from the first material, forming a part of the first inner surface, and arranged with the second portion in the first direction, wherein
the second portion is positioned between the first portion and the third portion.

13. The collimator according to claim 12, wherein
the second portion forms at least one of a protruding portion protruding from the first portion in a second direction that the first inner surface faces, and a recessed portion recessed from the first portion in the second direction.

14. The collimator according to claim 10, wherein
a length of the first portion in one of the plurality of walls is longer than a length of the first portion in another one of the plurality of walls, in the first direction.

15. The collimator according to claim 10, wherein
the plurality of walls include a second inner surface positioned on an opposite side of the first inner surface, and
the second inner surface includes the second portion.

16. The collimator according to claim 10, further comprising:
a fourth portion made of an insulating fourth material different from the first material, and forming end portions of the plurality of walls in the first direction, wherein
the first portion is positioned between the fourth portion and the second portion.

17. The collimator according to claim 10, further comprising:
a first member made of the first material, and including the first portion; and
a second member made of the second material, including the second portion, and arranged with the first member in the first direction, wherein
the first member is fixed to the second member.
